(19) United States
(12) Patent Application Publication
(10) Pub. No.: US 2013/0258569 A1
(43) Pub. Date: Oct. 3, 2013

(54) STRENGTHENED GLASS ENCLOSURES AND METHOD

(71) Applicants: Jaymin Amin, Corning, NY (US); David John McEnroe, Corning, NY (US); Wendell P. Weeks, Corning, NY (US)

(72) Inventors: Jaymin Amin, Corning, NY (US); David John McEnroe, Corning, NY (US); Wendell P. Weeks, Corning, NY (US)

(21) Appl. No.: 13/877,469

(22) PCT Filed: Oct. 3, 2011
(86) PCT No.: PCT/US11/54552

§ 371 Date: Jun. 18, 2013

Related U.S. Application Data
(60) Provisional application No. 61/391,146, filed on Oct. 8, 2010.

(51) Int. Cl. C03B 23/047; H05K 5/02; C03B 17/02

(52) U.S. Cl. CPC C03B 23/047; C03B 17/025; H05K 5/0217
USPC 361/679.01; 65/104; 65/86; 65/30.14; 65/41; 428/34.4

(57) ABSTRACT

Disclosed are methods for making an enclosure having a three-dimensionally shaped glass wall portion comprising an initial step of shaping a glass charge into a preform having a preform cross-section corresponding in shape to a smaller cross-sectional shape for the three-dimensional glass wall portion. At least a surface portion of the preform is then finished if necessary to remove any visible optical surface defects therefrom and/or to meet geometric tolerances, and the preform is drawn along an elongation axis perpendicular to the preform cross-section to reduce or draw down the preform in size to the smaller cross-sectional shape for the three dimensional glass wall portion. The smaller cross-sectional shape or sections thereof are then tempered to provide a strengthened glass wall portion having a compressively stressed surface layer thereon.

### CROSS-REFERENCE TO RELATED APPLICATIONS

This application claims the benefit of priority under 35 U.S.C. §119 of U.S. Provisional Application Ser. No. 61/391,146 filed on Oct. 8, 2010 the content of which is relied upon and incorporated herein by reference in its entirety.

### BACKGROUND

The present disclosure is in the field of glass manufacture and particularly relates to the manufacture of thin-walled high-strength glass enclosures for electronic devices.

Conventional processes for the manufacture of glass enclosures include molding or pressing, blowing, drawing, spinning and casting. Such processes have long been used for the manufacture of products ranging from food containers to tableware to incandescent lamp envelopes to cathode ray tube bulbs to drawn tubing for applications such as fluorescent lighting and laboratory ware.

Most applications for traditional glass enclosures require neither glass free of coloring impurities nor a surface finish of optical quality. This is in contrast to flat glass for advanced technical applications such as display screens for televisions, computer monitors, and other consumer electronics devices including cell phones, laptop computers, and hand-held entertainment devices, where freedom from optical defects is typically essential.

Glass offers a number of advantages over metals and plastics for many container applications, including transparency, hardness, heat resistance, resistance to chemical attack, and high electrical resistivity. However, the fracture resistance of ordinary glass is not generally considered adequate for uses where exposure to physical impacts or high stress is expected. Thus glass tableware such as tumblers and flat glass for glazing is in many cases toughened by thermal or even chemical tempering where enhanced resistance to stress or impact breakage is required.

Because glass must be melted and formed at high temperatures, it has not generally been considered suitable for use in the fabrication of containers or shaped components for other enclosures where the application requires shape precision, optical clarity and/or an optical surface finish. Existing processes for the optical finishing of glass products with three-dimensionally curved surfaces, such as lenses and telescope mirror blanks, are not suitable for the finishing of container surfaces, and are prohibitively expensive. Thus existing technologies are not well suited for the manufacture of containers or enclosures requiring precision shapes and defect-free surfaces from glass.

### SUMMARY

The present disclosure provides glass enclosures and enclosure components of high shape precision that are substantially free of optical defects, and methods for making them. The components can be made from a wide variety of glasses, including glasses of optical quality and glasses amenable to thermal or chemical tempering. Further, the methods can be adapted to the production of axially-extending enclosures or enclosure components over a wide range of precision cross-sectional shapes.

In accordance with particular embodiments, the disclosure includes methods for making an enclosure having a three-dimensionally shaped glass wall portion comprising an initial step of shaping a glass charge into a preform having a preform cross-section corresponding in shape to a smaller cross-sectional shape for the three-dimensional glass wall portion. At least a surface portion of the preform is then finished if necessary to remove any visible optical surface defects therefrom and/or to meet geometric tolerances, and the preform is drawn along an elongation axis perpendicular to the preform cross-section to reduce or draw down the preform in size to the smaller cross-sectional shape for the three dimensional glass wall portion. The smaller cross-sectional shape or sections thereof are then tempered to provide a strengthened glass wall portion having a compressively stressed surface layer thereon.

Three-dimensionally shaped glass wall portions made in accordance with the foregoing methods can be produced in an almost unlimited variety of axially extending curved or angled cross-sectional shapes. Particular embodiments include open curved or angular shapes such as u-shapes or three-sided channel shapes, as well as closed shapes including angled and non-circular shapes. Examples include regular closed shapes of oval, square, triangular, or rectangular cross-section as well as irregular shapes such as splined shapes.

Enclosures or enclosure wall portions such as herein described provide electrical, chemical, and physical properties rendering them particularly well suited for use to enclose or partially enclose sensitive electronic circuitry, including electronic devices incorporating such circuitry. Thus the present disclosure further provides electronic devices, including for example electronic display devices, that are disposed at least partially within an enclosure comprising a three-dimensionally shaped glass wall portion. In particular embodiments, the shaped glass wall portion incorporates at least an external compressively stressed surface layer to enhance the strength of the enclosure, including compressively stressed shapes provided, for example, by thermal tempering, chemical tempering, or lamination.

### DESCRIPTION OF THE DRAWINGS

The presently disclosed methods and products are further described below with reference to the appended drawings, wherein:

FIG. 1 schematically illustrates a preform extrusion die outlet face;

FIG. 2 is a schematic illustration of a glass preform for an enclosure;

FIG. 3 is a schematic illustration of a drawn glass enclosure section; and

FIG. 4 is a photographic enlargement of an enclosure section end-face.

### DETAILED DESCRIPTION

While the methods set forth in the present description are adaptable to the production of a wide range of enclosures for a variety of technical applications, enclosure components provided in accordance with those methods are particularly useful for the production of chemically strengthened enclosure component for the full or partial enclosure of consumer electronics devices or components thereof. Accordingly the following detailed description includes examples and illustrations of enclosures suitable for such uses even though the present disclosure is not limited thereto.

The processes used to fabricate glass preforms suitable for the production of enclosures or enclosure components in accordance with the disclosed methods are not critical. Preforms of near-net cross-sectional shape can be provided, for example, by casting, pressing, machining, sagging, reforming or extrusion, and in many cases with a shape precision requiring little or no reshaping prior to finishing and drawing.

A further advantage of the disclosed methods is that they are not limited to the use of any particular glass composition. Embodiments of particular interest for the enclosure of consumer electronics are glasses free of visual surface and, preferably, bulk defects that can be effectively strengthened by tempering. Illustrative examples of suitable glasses include alkali silicate, alkali borosilicate, alkali aluminosilicate, and alkali boroaluminosilicate glasses that can be chemically tempered to high surface stress levels by ion-exchange processing at temperatures below their annealing points. Also useful are glasses containing nucleating agents that could be converted by post-forming heat treatments to semi-crystalline glass-ceramic enclosures of high strength and durability, as well as glasses doped with optically active components such as silver to provide polarization or other optically unique effects.

The elongation of a properly configured preform to provide the smaller (reduced) cross-section of the selected enclosure or enclosure portion is suitably carried out by preform heating and down-drawing from a conventional induction or resistance-heated draw furnace, although other drawing methods or equipment could alternatively be used. The use of some form of drawing, however, is a critical step in the production of enclosures and enclosure components in accordance with the present description. That is because the cross-sectional reductions provided by drawing, typically constituting reductions of at least 2:1 and up to 50:1 or higher in preform cross-sectional outer dimensions, effect a substantial and necessary reduction in the sizes of glass surface and preform shape defects in the drawn shapes.

Very high shape precision in enclosures designed for the protection of consumer electronics is typically required. That is, the smaller cross-sectional shape of the enclosure, at least including the glass wall portion thereof, must adhere closely to a customer-mandated shape specification. Advantageously, the methods of the present disclosure provide a smaller cross-sectional shape wherein at least one, and more typically all, cross-sectional dimension(s) of the smaller shape meet a shape specification for the smaller shape to within ±0.25%, and in some embodiments to within ±0.025%, of the corresponding dimension(s) of the shape specification.

Shape precision of this magnitude cannot be consistently maintained in conventional glass molding processes, but can be met for the case of a 10:1 down-draw size reduction by maintaining shape precision in a molded preform to within 0.3 mm. Similarly, residual glass surface flaws in preform surfaces are greatly reduced or healed when the glass surface is allowed to soften during the drawing process, in some cases to a degree such that, for a carefully fabricated preform, the step of removing visible optical surface defects from the preform can be effected in the course of the drawing process.

Further embodiments of the disclosed methods enable the fabrication of enclosures formed of multiple wall sections of the same or different glass compositions that are physically compatible. An example would be a case where an enclosure incorporating one transparent wall portion and one translucent, colored or opaque wall portion. Preforms of complex cross-sectional shape, fabricated by joining preform sections of differing shapes and/or compositions, can be drawn together if the temperature-viscosity characteristics of the glasses are similar at drawing temperatures and if their thermal expansion coefficients are similar over the cooling range from drawing temperature to room temperature. Alternatively two preform segments of the same or different glasses can be brought together and sealed in the course of drawing, again provided that the viscosity and expansion characteristics of the glasses are not too different. Suitable pairs or even larger groups of different glass compositions or shapes suitable for combining into such enclosures by these methods can be readily identified by routine experiment.

The disclosed methods are further described below with reference to the following illustrative example.

### EXAMPLE

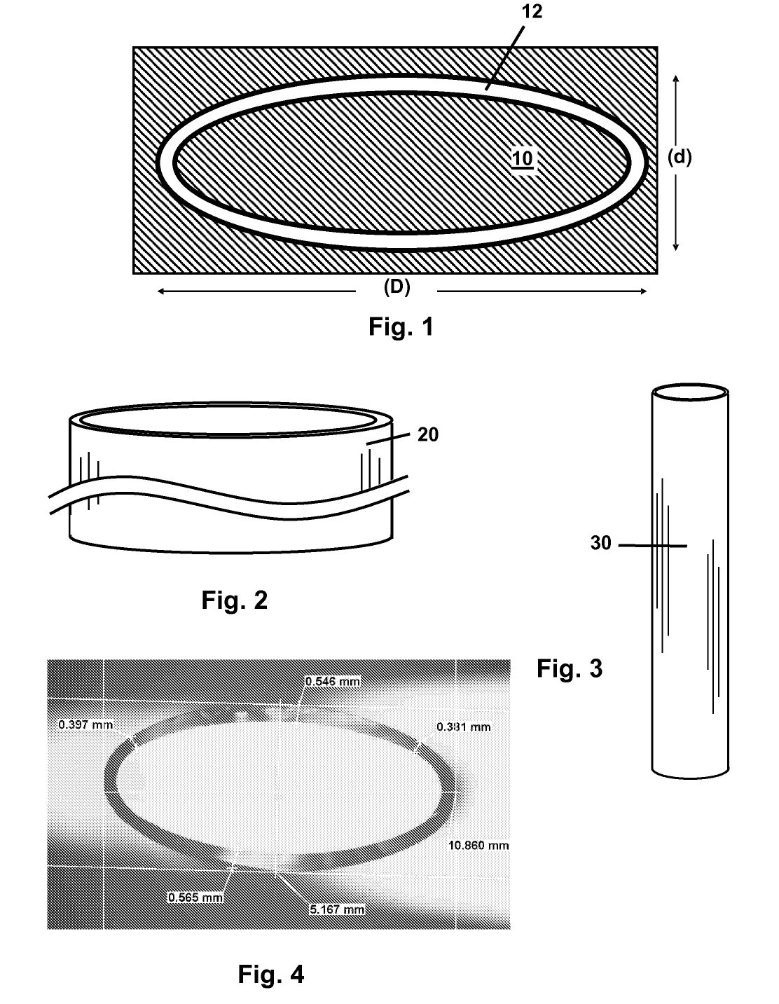

A tubular preform of oval cross-section, designed for drawing into an enclosure for an electronic circuit device, is fabricated via extrusion. As schematically illustrated in FIG. 1 of the drawings, a refractory metal extrusion die 10, machined to provide an oval discharge orifice 12 on its outlet face, is fabricated for shaping an oval preform having a major diameter (D) of 35.6 mm and a minor diameter (d) of 13.7 mm. The width of orifice 12 ranges from about 1.1 mm to about 1.3 mm.

A cylindrical boule of alkali aluminosilicate glass, having the composition of Corning Code 2318 glass, is melted from cullet and cast into a graphite mold 3.75 inches in diameter and 8 inches in depth. The boule is placed in the extruder barrel sitting on top of the die and the tooling is heated to 1050° C. Once thermal equilibrium is reached the glass is forced through the die by a plunger at pressures of several hundred kilograms at a viscosity in the range of 10⁵ to 10⁷ poise. The extruding oval is drawn from the die, cooled, and sectioned to provide tubular oval preforms approximately 5 feet in length. FIG. 2 of the drawings schematically illustrates the cross-sectional shape of a typical preform 20.

The tubular preform thus provided is cleaned by immersion in an aqueous acid solution comprising 5% HF+5% HCl+5% HNO₃ by weight for approximately 20 minutes. The tube was then rinsed with deionized water, then rinsed in methanol, and finally air-dried.

The cleaned preform is next clamped into the chuck of a downfeed mechanism positioned over the top opening of a three-zone electrical draw furnace and the chuck is aligned with the central axis of the opening. The furnace is then preheated to reach a top zone temperature of 830° C., a middle zone temperature of 950° C., and a bottom zone temperature of 725° C., with the glass preform being suspended over the top opening of the furnace.

After preheating the preform for 10 minutes it is lowered into the furnace heating zones at a feed rate of about 10 mm/min. Feeding continues until the bottom of the preform enters the middle heating zone of the furnace, and the preform is then held in that position until the bottom portion of the tube is heated sufficiently to soften and begin to elongate. The elongating or so-called “bait-off” end of the preform, which is reduced in size as the result of the elongation, is then fed into a downdraw tractor positioned below the furnace outlet for drawing, and the tractor is activated so that the attenuated end of the preform can be pulled downward at a controlled rate.

Once the downdrawing of the attenuating preform by the tractor has started, feeding of the preform into the top opening of the furnace is resumed at a controlled rate. The down-draw process is then brought under control by controlling the feeding speed of the preform, the temperature profile in the furnace, and the pulling speed of the tractor. These three variables dictate the reduction ratio achieved during the process, e.g., the ratio of the cross-sectional size or wall thickness of the preform to cross-sectional size or wall thickness of the smaller down-drawn product.

FIG. 3 of the drawings is a schematic illustration of a length of redrawn enclosure stock 30 of oval cross-section, not in true proportion or to scale, resulting from the down-drawing of a preform having the general configuration of the preform of FIG. 2. A reduction ratio of about 3:1 from a glass preform such as shown in FIG. 2 to a redraw enclosure section such as shown in FIG. 3 is easily provided utilizing the glass preform and drawing equipment of the present example.

In a typical procedure for drawing an enclosure section such as described from a Corning Code 2318 glass preform of the above size, the specified reduction is achieved using a preform downfeed speed rate of 40 mm/minute, a tractor pulling speed of 50 cm/minute, and a furnace temperature profile including a top zone temperature of 860° C., a middle zone temperature of 950° C., and a bottom zone temperature of 750° C. The drawing viscosity of the glass under these conditions is about 10⁶ poise.

FIG. 4 of the drawings is an enlarged photograph of a cut end face of a glass enclosure section drawn from a glass preform in accordance with the present example. The cross-sectional dimensions of the enclosure section, recorded on the photograph, indicate that a reduction ratio of about 3.1:1 has been achieved, and that the cross-sectional shape provided in the starting preform has been substantially retained. Larger or smaller reduction ratios are also provided utilizing the same glass and drawing equipment by varying the preform feeding rate, drawing rate, and/or draw furnace temperature profile. Of course, as is well known, the successful drawing of other glasses will depend on the composition and viscosity-temperature profile of the particular glass selected for processing, but the correct feeding and pulling rates as well as the optimum furnace temperature profile can readily be determined by routine experiment.

It will be appreciated from the foregoing descriptions that the particular compositions, products, methods and/or apparatus disclosed herein have been presented for purposes of illustration only, and that numerous adaptations and modifications thereof may be adopted to meet the requirements of new as well as existing applications within scope of the appended claims.

What is claimed is:

1. A method for making an enclosure comprising a three-dimensionally shaped glass wall portion comprising:
shaping a glass charge into a preform having a preform cross-section corresponding in shape to a smaller cross-sectional shape for a three-dimensional glass wall portion;
finishing a surface portion of the preform to adjust preform geometry or remove visible surface defects therefrom;
drawing the preform along an elongation axis perpendicular to the preform cross-section to reduce the preform to the smaller cross-sectional shape, and
tempering the smaller cross-sectional shape to provide a glass wall portion having compressively stressed surface layer thereon.

2. A method in accordance with claim 1 wherein a size ratio between the preform cross-section and the smaller cross-sectional shape is in the range of 2:1 to 50:1.

3. A method in accordance with claim 1 wherein the smaller cross-sectional shape comprises at least one cross-sectional dimension meeting a shape specification for the smaller cross-sectional shape to within 0.25% of a corresponding dimension of the shape specification.

4. A method in accordance with claim 1 wherein the smaller cross-sectional shape comprises at least one cross-sectional dimension meeting a shape specification for the smaller cross-sectional shape to within 0.025% of a corresponding dimension of the shape specification.

5. A method in accordance with claim 1 wherein the preform cross-section incorporates sections of two or more different glasses.

6. A method in accordance with claim 5 wherein the preform cross-section comprises a transparent section and a translucent, colored or opaque section.

7. A method in accordance with claim 1 wherein the preform is formed by a process selected from the group consisting of casting, pressing, machining, sagging, reforming and extrusion.

8. A method in accordance with claim 1 wherein the glass wall portion is tempered by a chemical ion-exchange process.

9. A method in accordance with claim 1 wherein the glass wall portion is strengthened by a co-drawn, laminated compression glass layer.

10. A method in accordance with claim 1 wherein the glass wall portion has a cross-sectional shape of open u-shape or 3-sided channel shape configuration.

11. A method in accordance with claim 1 wherein the glass wall portion has a closed non-circular cross-sectional shape selected from the group consisting of oval, square, splined, triangular and rectangular shapes.

12. A method in accordance with claim 1 wherein the glass wall portion has a cross-section comprising sections of two or more glasses of differing composition.

13. A method in accordance with claim 12 wherein the sections of two different glasses are fused together prior to or during the step of drawing.

14. A three-dimensionally shaped glass wall portion made in accordance with claim 1

15. An electronic display device disposed at least partially within an enclosure comprising a three-dimensionally shaped glass wall portion, the shaped glass wall portion incorporating an external compressively stressed surface layer.
